(19) United States
(12) Patent Application Publication
(10) Pub. No.: US 2021/0111361 A1
(43) Pub. Date: Apr. 15, 2021

(54) SEMI-TRANSPARENT SOLAR CELL DEVICE AND APPLICATION

(71) Applicant: SOUTH CHINA UNIVERSITY OF TECHNOLOGY, Guangzhou City (CN)

(72) Inventors: Hin Lap YIP, Guangzhou City (CN); Chen SUN, Guangzhou City (CN); Ruoxi XIA, Guangzhou City (CN); Fei HUANG, Guangzhou City (CN); Yong CAO, Guangzhou City (CN)

(73) Assignee: SOUTH CHINA UNIVERSITY OF TECHNOLOGY, Guangzhou City (CN)

(21) Appl. No.: 16/499,282

(22) PCT Filed: Nov. 28, 2017
(86) PCT No.: PCT/CN2017/113363

§ 371 Date: Sep. 29, 2019

(30) Foreign Application Priority Data
Mar. 31, 2017 (CN) 201710209714.7

(51) Int. Cl. H01L 51/44

(52) U.S. Cl. CPC H01L 51/442; H01L 51/447

(57) ABSTRACT

Disclosed are a semi-transparent solar cell device and an application. The cell device comprises a cathode, a hole transport layer, a photoactivity layer, an electron transport layer and an anode, wherein the photoactivity layer absorbs near-infrared and infrared light with a wavelength range greater than 780 nm. The cell device fully utilizes light energy in different bands, thus increasing the light energy utilization rate. By combining a semi-transparent solar cell and a heat-insulating film, not only can the cell device be used for generating power as a photovoltaic cell, but the device can also be attached to glass of a car or of an exterior wall of a building to be used as the heat-insulating film because of having excellent heat insulation performance itself. The cell device solves the problems of high visible light transmittance, high photoelectric conversion efficiency, heat insulation, ultraviolet protection, etc. required by smart windows of a car and a building in one go, and has the advantage of being environmentally friendly and energy saving.

### TECHNICAL FIELD

The present invention belongs to the technical field of photoelectric materials and devices, and relates to a semi-transparent solar cell device that can be applied to an automobile or an exterior wall of a building as a smart window.

### BACKGROUND ART

New solution-processable solar cells, which are represented by organic solar cells, have attracted much attention in recent years owing to their advantages of being soft, light in weight, as well as printable and producible in a large scale. Compared with traditional inorganic silicon solar cells, the absorption spectrum of the photoactive layer in such a new cell can be adjusted, in order to achieve absorption in different wave bands, and therefore the new cell can be applied to an smart window as a semi-transparent solar cell device, which has a huge market potential.

In terms of commercial applications, solar heat-insulating films have been widely applied to automobiles and the exterior walls of buildings, and the excellent heat insulation properties of the film can maintain the indoor temperature comfortable in all seasons, for example, reducing the heat entering the room in summer, so as to reduce the operating costs of air conditioning, while reducing the heat loss in winter. In addition, the most solar films for buildings or automobiles can block UV rays, extend the service life of indoor furniture and clothing, reduce glare and discomfort to the eyes, and provide a more energy-saving and comfortable environment. However, the currently available heat-insulating films in the market allow the most part of visible light to pass through, and reflect or scatter the invisible light, without truly effectively utilizing the energy.

### SUMMARY OF THE INVENTION

The primary objective of the present invention is to provide a semi-transparent solar cell device that can be applied to an automobile and an exterior wall of a building. The material of the photoactive layer in the solar cell is a solution-processable organic material, a dye-sensitized material, or an organic-inorganic hybrid cell material having a perovskite structure. The photoactive layer absorbs the light in the wave bands other than the visible light, especially the light in the infrared and near infrared wave bands. By adjusting the absorption spectrum of the light absorption layer in the solar cell and by adjusting the light field distribution in the device through an optical adjustment layer, the visible light is transmitted while the invisible light is reflected or scattered as far as possible, so that the light is absorbed and utilized by the photoactive layer.

Another objective of the present invention is to provide a new heat-insulating film for an automobile or a building. A semi-transparent solar cell is combined with a heat-insulating film, so that the light in the infrared part that mainly generates heat is absorbed and utilized by the light absorption layer, thereby imparting excellent heat insulation properties to such a device. The light energy in different wave bands is fully utilized, the utilization rate of the solar energy is improved, and theoretical and technical guidance are provided for futuristic development of new smart window materials for automobiles or buildings.

The objectives of the present invention are achieved by the following schemes:

A semi-transparent solar cell device, comprising an anode, a hole transport layer, a photoactive layer, an electron transport layer, and a cathode. the photoactive layer absorbs the light in near infrared and infrared wave bands in the wavelength range above 780 nm.

The donor and acceptor materials in the photoactive layer are solution-processable organic polymers having a conjugated backbone, or small molecule materials, and blends of the organic polymers and the small molecule materials.

The solution processing method for the photoactive layer is as follows: the donor and acceptor materials are mixed at a molar ratio of 1:10 to 10:1, dissolved in an organic solvent (such as chlorobenzene and o-dichlorobenzene), and formed into the photoactive layer by coating or evaporation.

The method for coating can be spin coating, brush coating, spray coating, dip coating, roll coating, screen printing, printing, or inkjet printing.

The donor and acceptor materials are preferably PBDTTT-E-T and IEICO.

The thicknesses of the anode, the hole transport layer, the photoactive layer, the electron transport layer and the cathode are 150±30 nm, 40±10 nm, 100±20 nm, 10±5 nm, and 10 nm to 20 nm, respectively.

The electron transport layer is preferably an organic conjugated polymer containing a highly polar group. The electron transport layer may be a composite interface layer obtained after the addition of nanoparticles which improve the light absorption.

The highly polar group in the electron transport layer is one or more of an amine group, a quaternary ammonium group, a phosphate group, a phosphate ester group, a sulfonate group, a carboxyl group, and a hydroxyl group.

The electron transport layer is preferably PNDIT-F3N-Br.

The hole transport layer is an organic conjugated polymer (which is preferably poly(3,4-ethylenedioxythiophene)/polystyrene sulfonate) or an inorganic semiconductor. The hole transport layer may be a composite interface layer obtained after the addition of nanoparticles which improve the light absorption.

The cathode is further coated with an optical adjustment layer. The optical adjustment layer is an adjustable multilayer structure composed of an optical material.

The cathode is aluminum, silver, gold, calcium/aluminum alloy, or calcium/silver alloy.

The anode is a metal or a metal oxide, such as at least one of an indium tin oxide conductive film (ITO), fluorine-doped tin dioxide (FTO), zinc oxide (ZnO), indium gallium zinc oxide (IGZO), graphene, and derivatives thereof.

The semi-transparent solar cell device has heat insulation properties and can be used as a heat-insulating film.

The device can be attached to the glass of an automobile or of an exterior wall of a building as a smart window.

In the present invention, by adjusting the absorption spectrum of the light absorption layer in the solar cell and by adjusting the light field distribution in the device through an optical adjustment layer, the visible light is transmitted while the invisible light is reflected or scattered as far as possible, so that the light is absorbed and utilized by the photoactive layer.

Compared with the prior art, the advantages of the present invention are as follows:

1. In the present invention, by adjusting the absorption spectrum of the light absorption layer in the solar cell, the visible light is transmitted while the invisible light is reflected or scattered as far as possible, so that the light is absorbed and utilized by the photoactive layer, thereby improving the photoelectric conversion efficiency of the semi-transparent solar cell.

2. The device in the present invention fully utilizes light energy in different wave bands, improves the utilization rate of solar energy. By combining the semi-transparent solar cell with a heat-insulating film, the device may not only be used as a photovoltaic cell for power generation, but may also be attached to the glass of an automobile or of an exterior wall of a building as a heat-insulating film, owing to the excellent heat insulation properties of the device itself. The device fulfills the requirements of a high visible light transmittance, high photoelectric conversion efficiency, heat insulation, UV protection, and the like, on smart windows of automobiles and buildings altogether.

### BRIEF DESCRIPTION OF DRAWINGS

FIG. 1 is a diagram showing the absorption spectrum of a photoactive layer film used in Example 1;

FIG. 2 is a diagram of the current-voltage curves of the semi-transparent solar cell devices using silver electrodes of different thicknesses in Example 1;

FIG. 3 is a diagram of the curves for the external quantum efficiency of the semi-transparent solar cell devices using silver electrodes of different thicknesses in Example 1;

FIG. 4 is a diagram of the transmittances of the semi-transparent solar cell devices using silver electrodes of different thicknesses in Example 1; and

FIG. 5 is a schematic structural diagram of the semi-transparent solar cell device according to the present invention.

### DETAILED DESCRIPTION OF EMBODIMENTS

The present invention is further described below using particular examples, specifically including material characterization, device preparation, and property tests.

### Example 1

Preparations of a Semi-Transparent Solar Cell Device:

Pieces of ITO conductive glasses, i.e. square sheets with a sheet resistance of about 20 ohm/square and the specification of 15 millimeters×15 millimeters. The sheets were clean by ultrasonic in acetone, a special detergent for micron-scale semiconductors, deionized water, and isopropanol sequentially for more than half an hour, and were then placed in a thermostatic oven for later use. The ITO glass sheets were treated with oxygen plasma for 4 minutes before use. An aqueous dispersion (Clevios P VP AI 4083, purchased from Bayer Corporation) of PEDOT:PSS (poly(3,4-ethylenedioxythiophene)/polystyrene sulfonate) was spin-coated as a hole transport layer onto the ITO at a high speed using a spin coater (KW-4A). A film thickness of about 40 nanometers was optimal. The thickness was determined by the concentration of the solution and the rotation speed, and was actually measured and monitored by a surface profiler (Alpha-Tencor-500 from Tritek Corporation). After formation, the film was heated in the air at 150° C. for 20 minutes and transferred into a glove box for later use. The photoactive layer material PBDTTT-E-T:IEICO (at a molar ratio of PBDTTT-E-T to IEICO of 1:1, and both are available from Solarmer) was dissolved in a solvent of chlorobenzene at a concentration of 12 milligram/milliliter, was spin-coated onto the PEDOT:PSS layer at a rotation speed of 1200 rpm, and then was heated at 100° C. and annealed for 10 minutes. The photoactive layer had a thickness of 80 nanometers to 100 nanometers. The electron transport layer was obtained by spin-coating a layer of PNDIT-F3N-Br solution onto the surface of the photoactive layer. A solid of PNDIT-F3N-Br (prepared according to the method reported in the patent CN 104725613 A) was dissolved in a methanol solvent at a concentration of 1 milligram/milliliter, and was spin-coated at a rotation speed of 2000 rpm, so as to obtain an electron transport layer film having a film thickness of about 10 nanometers. Finally, silver electrodes of different thicknesses were evaporated in a vacuum evaporation method to obtain semi-transparent solar cell devices with different transmittances.

FIG. 1 is a diagram showing the absorption spectrum of a photoactive layer film used in Example 1. The photoactive layer material had a film absorption edge at up to 900 nanometers, which was beyond the visible light region, and had relatively strong light absorption in the near infrared light region.

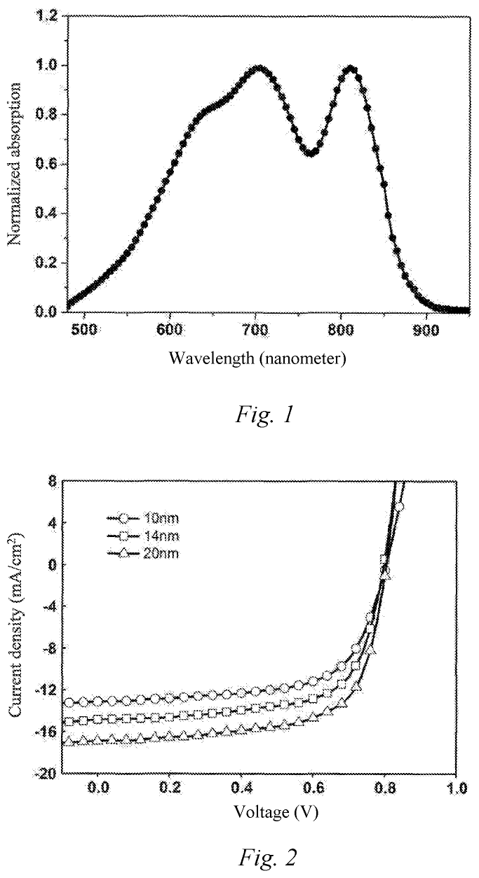

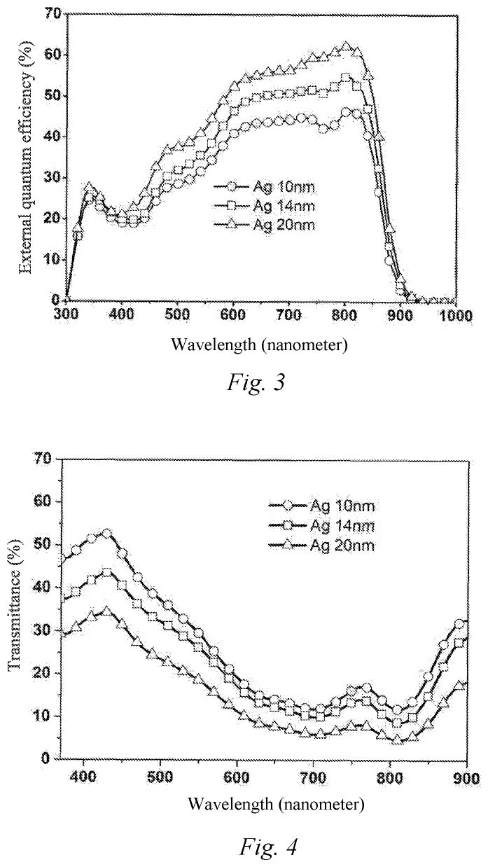

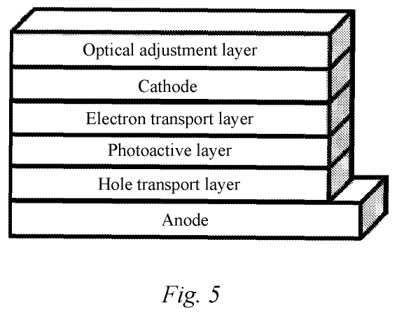

FIG. 2 is a diagram of the current-voltage curves of the semi-transparent solar cell devices using silver electrodes of different thicknesses in Example 1. The device structure used was that of a normal device: ITO/PEDOT:PSS/photoactive layer/PNDIT-F3N-Br/silver electrode. As can be seen from FIG. 2, as the thickness of the silver electrode increases, the reflection of light at the electrode increases, the short-circuit current of the device gradually increases, the open-circuit voltage and the fill factor of the devices remain substantially unchanged, and the photoelectric conversion efficiency of the eventual device also increases gradually. With this structure, when the thickness of the silver electrode was 10 nanometers, 14 nanometers, and 20 nanometers, the efficiency of the device was 6.8%, 7.9%, and 9.0%, respectively.

The specific efficiency of the solar cell device is shown in Table 1. In the table, V_{oc}, J_{sc}, FF, PCE, and Best PCE refer to the open-circuit voltage, the short-circuit current, the fill factor, the photoelectric conversion efficiency, and the maximum photoelectric conversion efficiency, respectively.

TABLE 1
Analysis of the efficiency of the semi-transparent solar cell
devices using silver electrodes of different thicknesses

| | | | | | Best |
|---|---|---|---|---|---|
| Silver electrode | V_{OC} | J_{SC} | | PCE | PCE |
| thickness | (V) | (mA/cm²) | FF | (%) | (%) |
| 10 nanometers | 0.81 ± 0.01 | 12.6 ± 0.5 | 0.65 ± 0.01 | 6.4 ± 0.4 | 6.8 |
| 14 nanometers | 0.81 ± 0.01 | 14.4 ± 0.4 | 0.66 ± 0.01 | 7.7 ± 0.3 | 7.9 |
| 20 nanometers | 0.81 ± 0.01 | 16.6 ± 0.3 | 0.67 ± 0.01 | 8.7 ± 0.3 | 9.0 |

The exact average visible light (380 nanometers to 780 nanometers) transmittances for different silver electrode thicknesses are shown in Table 2. According to the analysis of device efficiency in Table 1, a semi-transparent solar cell device prepared with this light absorption layer material can achieve better photoelectric conversion efficiency (up to 7%) while maintaining a relatively high average visible light transmittance (up to 20%). The main reason is that the light absorption layer material has relatively strong absorption in the near infrared region, and the photons absorbed in this region contribute to the improvement of the short-circuit current of the device, but do not affect the average visible light transmittance of the device overall. As can be inferred, other similar photoactive layer materials with absorption in near infrared may also achieve similar effects.

TABLE 2
Average visible light (380 nanometers to 780 nanometers)
transmittances of the semi-transparent solar cell devices

| Silver electrode | Average visible light |
|---|---|
| thickness | transmittance (%) |
| 10 nanometers | 27.8 |
| 14 nanometers | 23.7 |
| 20 nanometers | 17.0 |

### Example 2

### Heat Insulation Property Test for Semi-Transparent Solar Cell:

The semi-transparent solar cell device prepared in Example 1 was placed in a solar film tester (LS182 of Linshang) to test the heat insulation properties of the device. The exact properties are shown in Table 3. As can be learned from Table 3, such semi-transparent solar cells using silver electrodes of different thicknesses all have relatively high infrared blocking rates (greater than 70%). Moreover, when the thickness of the silver electrode is 20 nanometers, the infrared blocking rate of the silver electrode reaches 90% already, indicating that it has an excellent heat insulation effect. The heat insulation effect originates not only from the light absorption in the infrared region by the photoactive layer, but also from the reflection effect of the silver electrode on the infrared ray. In addition, the utilization rate of the light in the infrared region by the entire device can be further enhanced by adjusting the light intensity distribution in the device through an optical adjustment layer.

TABLE 3
Transmittances and heat insulation properties of different films

| | Visible light | Infrared blocking |
|---|---|---|
| | transmittance (%) | rate (%) |
| Glass | 90.4 | 10.3 |
| Silver electrode | 25.1 | 75.0 |
| of 10 nanometers | | |
| Silver electrode | 23.8 | 81.0 |
| of 14 nanometers | | |
| Silver electrode | 17.7 | 90.0 |
| of 20 nanometers | | |

As can be learned from Example 1 and Example 2, the light absorption property of the material was adjusted, and a light absorption layer material having a relatively strong absorption in the near infrared region was used, so that the semi-transparent solar cell device can achieve better photoelectric conversion efficiency while maintaining a relatively high average visible light transmittance. In addition, since the semi-transparent film device has a relatively high infrared blocking rate, the device can be used as a heat-insulating film on automobiles and the exterior walls of buildings.

The above-described embodiments are preferred embodiments of the present invention; however, the embodiments of the present invention are not limited to the above-described embodiments, and any other change, modification, replacement, combination, and simplification made without departing from the spirit, essence, and principle of the present invention should be an equivalent replacement and should be included within the scope of protection of the present invention.

1. A semi-transparent solar cell device, wherein the semi-transparent solar cell device comprises an anode, a hole transport layer, a photoactive layer, an electron transport layer and a cathode; and the photoactive layer absorbs the light in near infrared and infrared wave bands in the wavelength range above 780 nm.

2. The semi-transparent solar cell device according to claim 1, wherein the donor and acceptor materials in the photoactive layer are solution-processable organic polymers having a conjugated backbone, or small molecule materials, and blends of the organic polymers and the small molecule materials.

3. The semi-transparent solar cell device according to claim 2, wherein the solution processing method for the photoactive layer is as follows: the donor and acceptor materials are mixed at a molar ratio of 1:10 to 10:1, dissolved in an organic solvent, and formed into the photoactive layer by coating or evaporation.

4. The semi-transparent solar cell device according to claim 3, wherein the donor and acceptor materials are PBDTTT-E-T and IEICO.

5. The semi-transparent solar cell device according to claim 4, wherein the thicknesses of the anode, the hole transport layer, the photoactive layer, the electron transport layer and the cathode are 150±30 nm, 40±10 nm, 100±20 nm, 10±5 nm, and 10 nm to 20 nm, respectively.

6. The semi-transparent solar cell device according to claim 5, wherein the electron transport layer is PNDIT-F3N-Br; and the hole transport layer is poly(3,4-ethylenedioxythiophene)/polystyrene sulfonate.

7. The semi-transparent solar cell device according to claim 6, wherein both the electron transport layer and the hole transport layer are composite interface layers obtained after the addition of nanoparticles which improve the light absorption.

8. The semi-transparent solar cell device according to claim 1, wherein
the cathode is further coated with an optical adjustment layer; the cathode is aluminum, silver, gold, calcium/aluminum alloy, or calcium/silver alloy; and the anode is at least one of an indium tin oxide conductive film (ITO), fluorine-doped tin dioxide (FTO), zinc oxide (ZnO), indium gallium zinc oxide (IGZO), graphene, and derivatives thereof.

9. Use of the semi-transparent solar cell device according to claim 1, wherein the device is used as a heat-insulating film.

10. The use according to claim 9, wherein the device is attached to the glass of an automobile or of an exterior wall of a building.
